(19) United States
(12) Patent Application Publication
(10) Pub. No.: US 2011/0267049 A1
(43) Pub. Date: Nov. 3, 2011

(54) OPTICAL FIBER MAGNETO-OPTICAL DETECTING DEVICE

(76) Inventor: Haijun Yuan, Shanghai (CN)

(21) Appl. No.: 13/143,109

(22) PCT Filed: Dec. 31, 2009
(86) PCT No.: PCT/CN09/76354

§ 371 Date: Jul. 1, 2011

(30) Foreign Application Priority Data
Jan. 4, 2009 (CN) 200910056801.9

(51) Int. Cl. G01R 33/032

(52) U.S. Cl. 324/244.1

(57) ABSTRACT

An optical fiber magneto-optical detecting device comprises: a light-guiding input part (10) used for importing polarized light; a Faraday magneto-optical rotator (2), which is a magneto-optical crystal and used for affecting the intensity of the polarized light depending on a change of a magnetic field; a light-guiding output part (30) for exporting the polarized light; and a compensation unit (1a, 1b) used for rotating the imported polarized light, thus avoiding near-zero desensitization, and for compensating the temperature error of the magneto-optical crystal. The compensation unit (1a, 1b) is provided between the light-guiding input part (10) and the Faraday magneto-optical rotator (2) or between the Faraday magneto-optical rotator (2) and the light-guiding output part (30).

### FIELD OF THE INVENTION

The present invention relates to the field of optical application, particularly to an optical fiber magneto-optical detecting device.

### BACKGROUND OF THE INVENTION

Magneto-optical crystals are widely used in the light intensity and light path control in the optical fiber communication as well as the magnetic field and electrical current measurement in other fields. Garnet magneto-optical crystal is one of the magneto-optical crystals which are used in the relative wide range. Hereinafter, explanations will be given, taking the Garnet magneto-optical crystal as an example.

In most cases, a stripe shaped complex magnetic domain structure is formed inside a multi-crystal Garnet magneto-optical crystal. FIG. 1 illustrates a microgram of the magnetic domain structure of a single-crystal Garnet magneto-optical crystal, and FIG. 2 schematically illustrates the magnetic domain structure of the single-crystal Garnet magneto-optical crystal. As shown in FIG. 1, even in the case of the single-crystal Garnet magneto-optical crystal, the stripe shaped complex magnetic domain structure is usually also formed therein. In general, the adjacent magnetic domains have the magnetization directions which are perpendicular to the crystal surface but opposite to each other, as shown in FIG. 2.

When being under the effect of an external magnetic field, among the adjacent magnetic domain areas of the magneto-optical crystal, one becomes larger relatively and the other becomes smaller relatively, along with the changes in the intensity and direction of the external magnetic field. When the external magnetic field exceeds the saturation magnetic field of the material, the complex magnetic domain is changed into the unitary uniform magnetic domain having unitary magnetization direction. When the intensity of the external magnetic field is reduced, the complex magnetic domain is reformed. These two kinds of magnetic domain areas are evenly distributed when the external magnetic field is withdrawn. Such process corresponds to different magneto-optical effects and intensity changes of the crystal, and thus leads to various applications.

FIG. 3 schematically illustrates a structure of an optical fiber magneto-optical detecting device in the prior art, which includes an input optical fiber 6, an input light collimator 5a, a first light polarization splitter 3d, a magneto-optical crystal 1, a half wave plate 2, a second light polarization splitter 3e, an output light collimator 5b and an output optical fiber 7.

The optical fiber magneto-optical detecting device uses a process of light polarization, to perform wave separation, magneto-optical induction and wave combination on the orthogonal polarization components of the light.

A wave plate is provided in rear of a Faraday magneto-optical rotator, and the wave plate is used to planes of the two beams of light output from the Faraday magneto-optical rotator, so as to avoid near-zero desensitization, while the magneto-optical induction and the polarization detection made to the two orthogonal polarization components at the same time and in the same quantity. The first light polarization splitter 3d and the second light polarization splitter 3e are made of single-axis crystal and can separate the two beams of orthogonal polarized light with a certain angle. After the light passes through the first light polarization splitter 3d, it is divided into two beams of light with the polarization planes orthogonal to each other. The propagating directions of the two beams of light have a small angle between them, and pass through the magneto-optical crystal 1 and the half wave plate 2 simultaneously. Upon the two beams of light arrive at the second light polarization splitter 3e, the component propagating directions of each light beam, whose the polarization plane rotates by the angle of 90° relative to the initial polarization plane generated by the first light polarization splitter 3d, will become identical. Although there is a slight separation space between the two beams of light, they can be received by the output light collimator 5b and the output optical fiber 7 equally, while other components will be insulated from the output optical fiber 7.

It a Garnet magneto-optical crystal is used as the Faraday magneto-optical rotator, when the incidence polarization plane of the light and the optical axis of the detecting polarizer forms an angle of α, the detected intensity varies along with the measured magnetic field in the relationship indicated by the following expression:

$$I ∝ {I}_{0} T [ \begin{matrix}{( 2 cos αcosφ )}^{2} + {( 2 sin αsinφ )}^{2} ( 1 - ζ + {ζ ( \frac{H}{{H}_{s}} )}^{2} ) + \\ 2 ( \frac{H}{{H}_{s}} ) sin 2 αsin 2 φ\end{matrix} ] \qquad ( 4 )$$

where I denotes the intensity of a light source, T is the transparency of an optical system, φ is a Faraday rotation angle of a crystal, α is the angle between the incidence polarization plane and a detecting polarizer, H is the measured magnetic field, H, is the saturation magnetic field of the crystal, and ζ is a parameter indicative of the interference degree of the light generated by the grid shaped magnetic domain structure, wherein α and φ are generally close to 45° in applications.

However, during the practice of the invention, the inventor found that, in general, φ and Hₛ, characterizing the magneto-optical crystal e.g. the Garnet magneto-optical crystals, vary along with the change of the temperature, which causes the measurement to vary along with the change of the temperature and leads to a temperature error.

### SUMMARY OF THE INVENTION

The object of the invention is to provide an optical fiber magneto-optical detecting device, which can solve the problems of the temperature error in the prior art.

In an embodiment of this invention, an optical fiber magneto-optical detecting device is provided, which comprises: a light-guiding input part used for importing polarized light, a Faraday magneto-optical rotator, which is a magneto-optical crystal and used for affecting the intensity of the polarized light depending on a change of a magnetic field, a light-guiding output part for exporting the polarized light. The optical fiber magneto-optical detecting device further comprises a compensation unit for rotating the imported polarized light, thus avoiding near-zero desensitization, and for compensating temperature error of the magneto-optical crystal. The compensation unit is provided between the light-guiding input part and the Faraday magneto-optical rotator or between the Faraday magneto-optical rotator and the light-guiding output part.

Alternatively, in the above optical fiber magneto-optical detecting device, the light-guiding input part comprises an input optical fiber to input a light beam, an input light collimator to collimate the input light beam so as to obtain a collimated light beam, and a first light polarization splitter to separate said light beam into two parallel light beams, the polarization planes of which are orthogonal to each other.

Alternatively, in the above optical fiber magneto-optical detecting device, the light-guiding output part comprises a second light polarization splitter to combine the two parallel light beams, an output light collimator to collimate the combined light beam, and an output optical fiber to output the collimated light beam.

Alternatively, in the above optical fiber magneto-optical detecting device, the magneto-optical crystal is a Garnet magneto-optical crystal.

Alternatively, in the above optical fiber magneto-optical detecting device, the compensation unit a wave plate system.

Alternatively, in the above optical fiber magneto-optical detecting device, the wave plate system includes: a first wave plate, which is a thick multiple-order quarter-wave plate; and a second wave plate, which is a common zero-order quarter-wave plate.

Alternatively, in the above optical fiber magneto-optical detecting device, the optical axis of the first wave plate and the crystal optical axis of the first light polarization splitter form an angle of 45°, and the optical axis of the second wave plate is parallel with or perpendicular to the crystal optical axis of the first light polarization splitter.

Alternatively, in the above optical fiber magneto-optical detecting device, the birefringence phase retardation of the first wave plate is (k+¼)λ at a reference temperature, where k is a thickness coefficient, the value of which is the number of the whole waves of the polarized light received in the thickness of the first wave plate, and λ is the wave length of the polarized light, wherein the thickness of the first wave plate varies according to the temperature, which leads to the change of k, such that the birefringence phase retardation varies, so as to generate temperature compensation effect.

Alternatively, in the above optical fiber magneto-optical detecting device, the thickness of the first wave plate is selected according to the temperature coefficient of the magneto-optical crystal and the temperature coefficient of the first wave plate.

Alternatively, in the above optical fiber magneto-optical detecting device, when the temperature varies, the Faraday rotation angle of the magneto-optical crystal is changed by a shift of Δφ, and the rotation angle of the birefringence phase retardation of the first wave plate is changed by a shift of −Δα. The thickness of the first wave plate is selected, such that Δα=Δφ.

In the above embodiment, the optical fiber magneto-optical detecting device is incorporated with a compensation unit, which is able to compensate the measurement error due to the temperature change, thus solving the problems of temperature error in the prior art.

### BRIEF DESCRIPTION OF THE DRAWINGS

Accompanying drawings illustrated herein are provided for further understanding of the present invention and form a part of the specification. The exemplary embodiments of the present invention and the description thereof are used for explaining the present invention, rather than limiting the present invention unduly, in which:

FIG. 1 illustrates a microgram of the magnetic domain structure of a single-crystal Garnet magneto-optical crystal;

FIG. 2 schematically illustrates the magnetic domain structure of the single-crystal Garnet magneto-optical crystal:

FIG. 3 schematically illustrates a structure of an optical fiber magneto-optical detecting device in the prior art;

FIG. 4 schematically illustrates a structure of an optical fiber magneto-optical detecting device according to an embodiment of the present invention; and

FIG. 5 schematically illustrates a structure of an optical fiber magneto-optical detecting device according to another embodiment of the present invention.

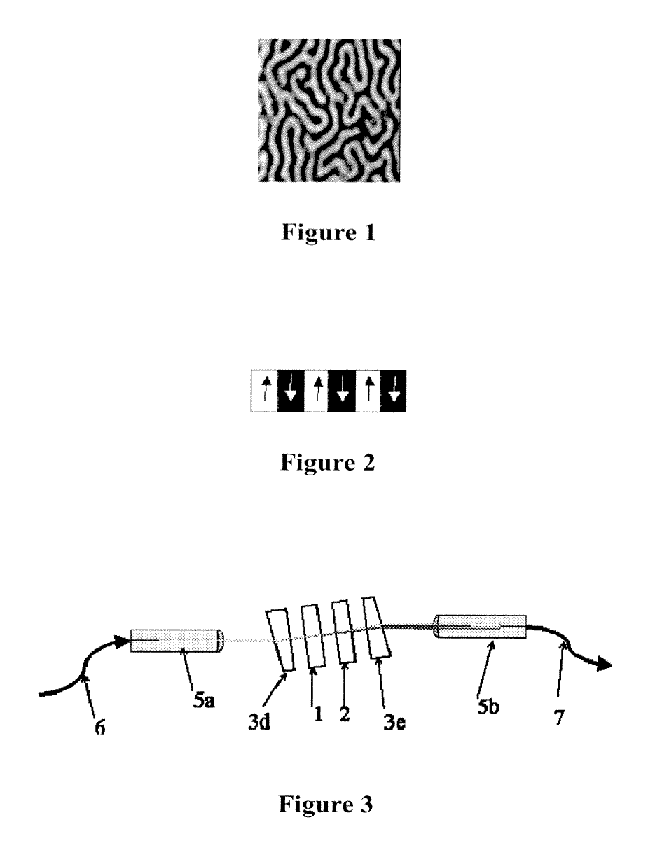

### DETAILED DESCRIPTION OF THE EMBODIMENTS

The present invention will be described in detail in connection with drawings and embodiments.

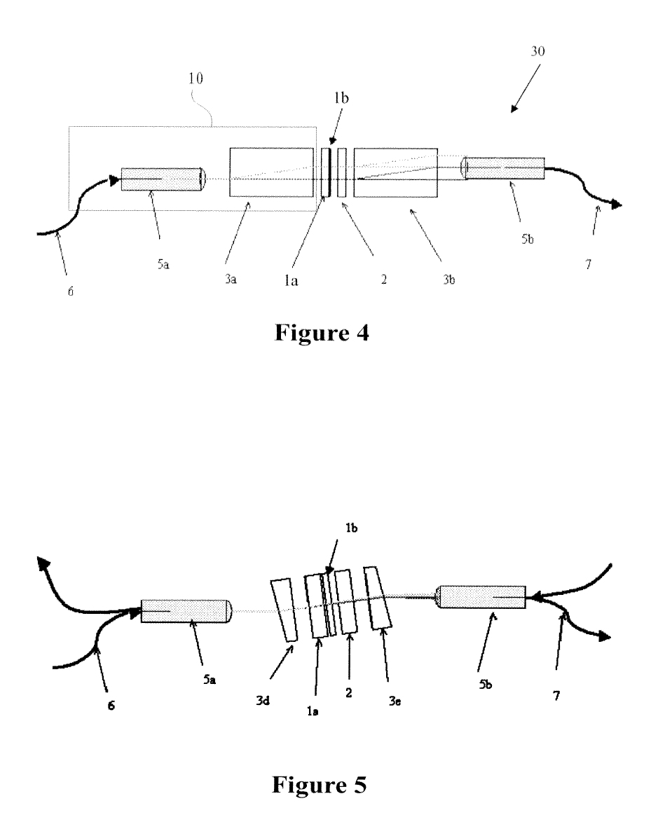

FIG. 4 schematically illustrates a structure of an optical fiber magneto-optical detecting device according to an embodiment of the present invention, which comprises:

a light-guiding input part 10, used for importing polarized light;

a Faraday magneto-optical rotator 2, which is a magneto-optical crystal and used for affecting the intensity of the polarized light depending on the change of a magnetic field;

a light-guiding output part 30, for exporting the polarized light;

a compensation unit 1a or 1b, used for rotating the imported polarized light, thus avoiding near-zero desensitization, and for compensating the temperature error of the magneto-optical crystal, wherein the compensation unit is provided between the light-guiding input part and the Faraday magneto-optical rotator or between the Faraday magneto-optical rotator and the light-guiding output part.

The optical fiber magneto-optical detecting device is incorporated with the compensation unit, which is able to compensate the measurement error due to the temperature change, thus solving the problems of temperature error in the prior art.

FIG. 5 schematically illustrates a structure of an optical fiber magneto-optical detecting device according to another embodiment of the present invention.

As illustrated in FIGS. 4 and 5, the light-guiding input part comprises:

an input optical fiber 6, to input a light beam:

an input light collimator 5a, to collimate the input light beam;

a first light polarization splitter 3a or 3d, to separate the light beam into two parallel light beams, the polarization planes of which are orthogonal to each other.

As illustrated in FIGS. 4 and 5, the light-guiding output part comprises:

a second light polarization splitter 3b or 3e, to combine the two parallel beams;

an output light collimator 5b, to collimate the combined light beam to obtain a collimated light beam;

an output optical fiber 7, to output the collimated light beam.

Alternatively, in the above optical fiber magneto-optical detecting device, the magneto-optical crystal is a Garnet magneto-optical crystal, which is one of the magneto-optical crystals which are used in a relative wide range.

The Faraday magneto-optical rotator is a Garnet magneto-optical crystal, which has stripe shaped complex magnetic domain structure and in which the adjacent magnetic domains have the magnetization directions which are perpendicular to the crystal surface but opposite to each other. When being under the effect of an external magnetic field, the adjacent magnetic domain areas vary depending on the intensity and direction of the external magnetic field, wherein one magnetic domain area becomes larger relatively, while the other one becomes smaller relatively. When the external magnetic field exceeds the saturation magnetic field of the material, the complex magnetic domain is changed into the unitary and uniform magnetic domain having unitary magnetization directions. When the intensity of the external magnetic field is reduced, the complex magnetic domain is reformed. These two kinds of magnetic domain areas are evenly distributed when the external magnetic field is withdrawn. The stripe shaped magnetic domains with opposite magnetization directions have the Faraday rotation angles φ, which are equal to each other but have opposite rotation directions, wherein within the range of the operation temperature, the Faraday rotation angle φ is close to the angle φ₀ at a reference temperature T₀, which is set to 45°, however, the Faraday rotation angle has a small change as the temperature varies.

As illustrated in FIGS. 4 and 5, the compensation unit 1a or 1b is formed by a wave plate system. The wave plate system can not only overcome the shortcomings of near-zero desensitization in the prior art, but also automatically compensate the error due to the temperature drifting.

The optical fiber magneto-optical detecting device in the above embodiments, including the light being guided by an optical fiber and a Faraday magneto-optical rotator, uses the light polarization process to perform the wave separation, magneto-optical induction and the wave combination on to the orthogonal polarization components of the light. The Faraday magneto-optical rotator is a Garnet magneto-optical crystal. The wave plate system is provided in front or rear of the Faraday magneto-optical rotator, and the wave plate system is used to rotate the polarization planes of the two beams of input light led into the Faraday magneto-optical rotator, so as to avoid near-zero desensitization. Furthermore, the wave plate system has a function of temperature compensation, which is able to compensate the measurement error due to the temperature change, wherein the polarization detection is made to the two orthogonal polarization components at the same time and in the same quantity.

The wave plate system includes: a first wave plate 1a, which is a thick multiple order quarter-wave plate; and a second wave plate 1b, which is a common zero-order quarter-wave plate. The positions of the first and second wave plates can be switched and the positions of the wave plate system thus composed and the magneto-optical crystal can also be switched. It is also possible to provide the magneto-optical crystal between the first wave plate and the second wave plate.

In addition, the first wave plate 1a and the second wave plate 1b together constitute a half wave plate, which can overcome the shortcomings of near-zero desensitization in the prior art. The first wave plate thereof also can serve for temperature compensation, which will be explained in detail in the following.

Alternatively, the optical axis of the first wave plate and the crystal optical axis of the first light polarization splitter form an angle of 45°, and the optical axis of the second wave plate is parallel with or perpendicular to the crystal optical axis of the first light polarization splitter.

Alternatively, the birefringence phase retardation of the first wave plate is (k+¼)λ at the reference temperature, where k is a thickness coefficient, the value of which is the number of the whole waves of the polarized light received in the thickness of the first wave plate, and λ is the wave length of the polarized light, wherein the thickness of the first wave plate varies according to the temperature, which leads to the change of k, such that the birefringence phase retardation varies so as to generate temperature compensation effects.

Alternatively, the thickness of the first wave plate is selected according to the temperature coefficient of the magneto-optical crystal and the temperature coefficient of the first wave plate.

Alternatively, when the temperature is changed, the Faraday rotation angle of the magneto-optical crystal is changed by a shift of Δφ, and the rotation angle of the birefringence phase retardation of the first wave plate is changed by a shift of −Δα. The thickness of the first wave plate is selected such that Δα=Δφ.

Specifically, the wave plate system s composed of two wave plates, i.e., the first wave plate and the second wave plate. The first wave plate is a thick multiple order quarter-wave plate and the birefringence phase retardation thereof is integer times of the used quarter wave, i.e., (k−¼)λ at reference temperature, wherein k is an integer. The temperature has an influence on the birefringence phase retardation of the first wave plate, and the influence becomes larger as the thickness increases, i.e., k increases. The integer k is selected according to the requirement of temperature compensation. The second wave plate is a common zero-order quarter-wave plate and the change of the birefringence phase retardation thereof along with the temperature may be ignored. The optical axis of the first wave plate and the crystal optical axis of the first light polarization splitter form an angle of 45°, and the optical axis of the second wave plate is parallel with or perpendicular to the crystal optical axis of the first light polarization splitter. Such arrangement makes the polarization planes of the two orthogonal beams of polarized light coming from the first light polarization splitter rotate by an angle of α after passing through the above wave plate system, wherein the angle α is determined fully by the phase retardation of the first wave plate, and α₀=45° at the reference temperature.

The function of temperature compensation of the wave plate system is carried out through the following approaches. For example, when the temperature increases, the Faraday rotation angle will be decreased from φ₀ to φ₀+Δφ, at the same time, the rotation angle of the polarization plane caused by the wave plate system will be increased from α₀ to α₀−Δα. The thickness, i.e., the integer k, of the first wave plate is properly selected according to the temperature coefficient of the Garnet magneto-optical crystal and the temperature coefficient of the material used for the wave plates, such that the influences on the intensity variety due to both of them are mutually compensated, thus obtaining temperature compensation effect.

The above description is only preferable embodiments of the present invention, which are not used to limit the present invention. For those skilled in the art, the present invention may have various changes and variations. Any amendments, equivalent substitutions, improvements etc. within the spirit and principle of the present invention are all concluded in the scope of protection of the present invention.

What is claimed is:

1. An optical fiber magneto-optical detecting device, characterized by comprising:
a light-guiding input part used for importing polarized light;
a Faraday magneto-optical rotator (2), which is a magneto-optical crystal and used for affecting the intensity of the polarized light depending on the change of a magnetic field; and
a light-guiding output part for exporting the polarized light;
and further comprising:
a compensation unit (1a, 1b) for rotating the imported polarized light, thus avoiding near-zero desensitization, and for compensating the temperature error of the magneto-optical crystal, wherein the compensation unit is provided between the light-guiding input part and the Faraday magneto-optical rotator (2) or between the Faraday magneto-optical rotator (2) and the light-guiding output part.

2. The optical fiber magneto-optical detecting device according to claim 1, characterized in that light-guiding input part comprises:
an input optical fiber (6) to input a light beam;
an input light collimator (5a) to collimate the input light beam; and
a first light polarization splitter (3a, 3d) to separate said light beam into two parallel light beams, the polarization planes of which are orthogonal to each other.

3. The optical fiber magneto-optical detecting device according to claim 2, characterized in that light-guiding output part comprises:
a second light polarization splitter (3b, 3e) to combine the two parallel light beams;
an output light collimator (5b) to collimate the combined light beam so as to obtain a collimated light beam; and
an output optical fiber (7) to output the collimated beam.

4. The optical fiber magneto-optical detecting device according to claim 1, characterized in that the magneto-optical crystal is a Garnet magneto-optical crystal.

5. The optical fiber magneto-optical detecting device according to claim 3, characterized in that the compensation unit is a wave plate system.

6. The optical fiber magneto-optical detecting device according to claim 5, characterized in that the wave plate system includes:
a first wave plate, which is a thick multiple-order quarter-wave plate; and
a second wave plate, which is a common zero-order quarter-wave plate.

7. The optical fiber magneto-optical detecting device according to claim 6, characterized in that,
the optical axis of the first wave plate and the crystal optical axis of the first light polarization splitter form an angle of 45°, and the optical axis of the second wave plate is parallel with or perpendicular to the crystal optical axis of the first light polarization splitter.

8. The optical fiber magneto-optical detecting device according to claim 6, characterized in that,
the birefringence phase retardation of the first wave plate is (k+¼)λ at a reference temperature,
where k is a thickness coefficient, the value of which is the number of the whole waves of the polarized light received in the thickness of the first wave plate, and λ is the wave length of the polarized light, wherein, the thickness of the first wave plate varies according to the temperature, which leads to the change of k such that the birefringence phase retardation varies so as to generate temperature compensation effect.

9. The optical fiber magneto-optical detecting device according to claim 8, characterized in that,
the thickness of the first wave plate is selected according to the temperature coefficient of the magneto-optical crystal and the temperature coefficient of the first wave plate.

10. The optical fiber magneto-optical detecting device according to claim 9, characterized in that,
when the temperature is changed, the Faraday rotation angle of the magneto-optical crystal is changed by a shift of Δφ, and
the rotation angle of the birefringence phase retardation of the first wave plate is changed by a shift of −Δα, and the thickness of the first wave plate is selected such that Δα−Δφ.
